(19) United States
(12) Patent Application Publication
(10) Pub. No.: US 2025/0081472 A1
(43) Pub. Date: Mar. 6, 2025

(54) NON-VOLATILE MEMORY DEVICE

(71) Applicant: Samsung Electronics Co., Ltd., Suwon-si (KR)

(72) Inventors: Sehoon Lee, Suwon-si (KR); Joonyoung Kwon, Suwon-si (KR); Junhyoung Kim, Suwon-si (KR); Sukkang Sung, Suwon-si (KR)

(21) Appl. No.: 18/766,970

(22) Filed: Jul. 9, 2024

(30) Foreign Application Priority Data
Sep. 4, 2023 (KR) 10-2023-0117231

(51) Int. Cl. H10B 80/00; H01L 25/065; H10B 41/27; H10B 41/41; H10B 43/27; H10B 43/40

(52) U.S. Cl. CPC H10B 80/00; H01L 25/0657; H10B 41/27; H10B 41/41; H10B 43/27; H10B 43/40; H01L 2225/06506; H01L 2225/06562; H01L 2225/06586

(57) ABSTRACT

A non-volatile memory device includes a substrate, a first semiconductor layer including a memory cell array on the substrate, a second semiconductor layer including a peripheral circuit that is configured to write data to or read the data from the memory cell array, where the second semiconductor layer is on the first semiconductor layer, and a protrusion structure including a wire that extends into at least a portion of the first semiconductor layer and at least a portion of the second semiconductor layer, where the protrusion structure extends from a first surface of the first semiconductor layer and from a first surface of the second semiconductor layer, and where the protrusion structure extends in a second direction that is perpendicular to the first direction.

### CROSS-REFERENCE TO RELATED APPLICATION

This application is based on and claims priority under 35 U.S.C. § 119 to Korean Patent Application No. 10-2023-0117231, filed on Sep. 4, 2023, in the Korean Intellectual Property Office, the disclosure of which is incorporated by reference herein in its entirety.

### TECHNICAL FIELD

The present disclosure relates to a non-volatile memory device, and more particularly, to a non-volatile memory device including a plurality of semiconductor chips.

### BACKGROUND

With information and communication devices recently becoming compact and multifunctional, memory devices are desired to have a high capacity and a high integration density. As the size of memory cells is reduced for high integration density, the complexity of operating circuits and/or wiring structures, which are included in memory devices for the operations and electrical connection thereof, has increased. Therefore, reducing the area of semiconductor chips by reducing the size of memory cells faces technical limits. However, the multifunctionalization and compactness of information and communication devices continues, and accordingly, reducing the size of semiconductor chips continues to be desired.

### SUMMARY

The present disclosure provides a non-volatile memory device having a high integration density by reducing the size of the non-volatile memory device.

Aspects of the present disclosure are not limited to those mentioned above, and other aspects that have not been mentioned will be clearly understood by one of skill in the art from the description below.

According to an aspect of the present disclosure, there is provided a non-volatile memory device including a substrate, a first semiconductor layer including a memory cell array on the substrate, where the memory cell array includes a plurality of gate conductive layers and defines a plurality of channel holes, where the plurality of gate conductive layers are spaced apart in a first direction that is perpendicular to a top surface of the substrate, and where each of the plurality of channel holes extend into the plurality of gate conductive layers, a second semiconductor layer including a peripheral circuit that is configured to write data to or read the data from the memory cell array, where the second semiconductor layer is on the first semiconductor layer, and a protrusion structure including a wire that extends into at least a portion of the first semiconductor layer and at least a portion of the second semiconductor layer, where the protrusion structure extends from a first surface of the first semiconductor layer and from a first surface of the second semiconductor layer, and where the protrusion structure extends in a second direction that is perpendicular to the first direction.

According to another aspect of the present disclosure, there is provided a memory package including a package substrate configured to electrically connect an external device to the memory package, a first memory device that extends in a first direction that is perpendicular to a top surface of the package substrate, where the first memory device includes a first surface, a second surface, a third surface, and a fourth surface, where the first surface is spaced apart from the second surface in a second direction that is perpendicular to the first direction, and where the third surface and the fourth surface extend from the first surface to the second surface, and a second memory device including a fifth surface, a sixth surface, a seventh surface, and an eighth surface, where the fifth surface is spaced apart from the sixth surface in the second direction, and where the seventh surface and the eighth surface extends from the fifth surface to the sixth surface, where the first memory device includes a first protrusion structure that extends from the first surface, where the second memory device includes a second protrusion structure that extends from the fifth surface, where the second memory device is on the first memory device, and where a bottom surface of the second protrusion structure overlaps at least a portion of the first memory device in the first direction.

According to a further aspect of the present disclosure, there is provided a memory package including a package substrate configured to electrically connect an external device to the memory package, a first memory device that extends in a first direction that is perpendicular to a top surface of the package substrate, where the first memory device includes a first surface, a second surface, a third surface, and a fourth surface, where the first surface is spaced apart from the second surface in a second direction that is perpendicular to the first direction, and where the third surface and the fourth surface extend from the first surface to the second surface, and a second memory device including a fifth surface, a sixth surface, a seventh surface, and an eighth surface, where the fifth surface is spaced apart from the sixth surface in the second direction, and where the seventh surface and the eighth surface extend from the fifth surface to the sixth surface, where the first memory device includes a first protrusion structure that extends from the first surface, where the second memory device includes a second protrusion structure that extends from the fifth surface, where the second memory device at least partially overlaps the first memory device in the first direction, and where the first protrusion structure is spaced apart from the second protrusion structure in a third direction that is perpendicular to the first direction and the second direction.

### BRIEF DESCRIPTION OF THE DRAWINGS

Embodiments will be more clearly understood from the following detailed description taken in conjunction with the accompanying drawings in which:

FIG. 1 is a diagram of a memory device according to some embodiments;

FIG. 2 is a circuit diagram of a memory block according to some embodiments;

FIG. 3 illustrates an example structure of the memory device of FIG. 1;

FIGS. 4A, 4B, 4C, and 4D are diagrams illustrating the arrangement of a memory device on a wafer, according to some embodiments;

FIGS. 5A and 5B are diagrams of a memory device according to some embodiments;

FIGS. 6A and 6B are cross-sectional views of a memory device according to some embodiments;

FIGS. 7A and 7B are diagrams illustrating a memory device according to some embodiments;

FIGS. 8A and 8B are diagrams illustrating a memory device according to some embodiments;

FIG. 9 is a cross-sectional view of a memory device having a bonding vertical NAND (BVNAND) structure according to some embodiments; and

FIG. 10 is a block diagram of an example of applying a memory device to a solid-state drive (SSD) system according to embodiments.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, embodiments are described in detail with reference to the accompanying drawings. In the drawing, like reference characters denote like elements, and redundant descriptions thereof will be omitted.

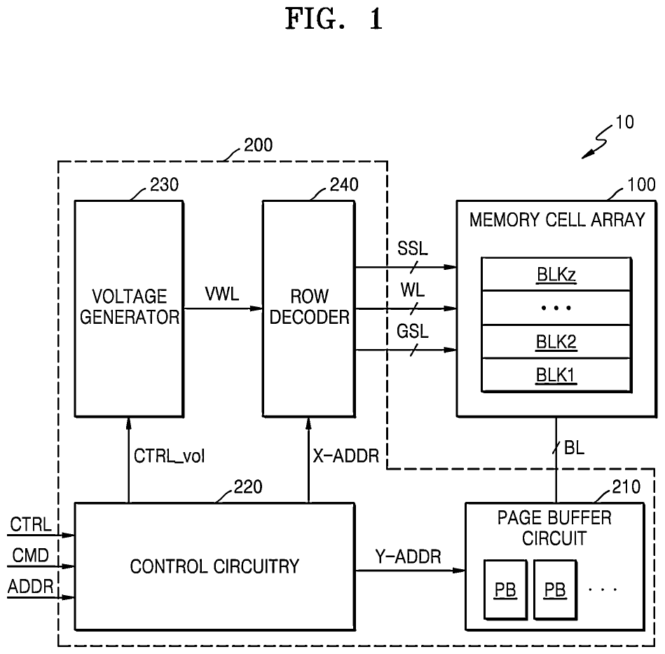

FIG. 1 is a diagram of a memory device 10 according to some embodiments.

Referring to FIG. 1, the memory device 10 may include a memory cell array 100 and a peripheral circuit 200. The peripheral circuit 200 may include a page buffer circuit 210, control circuitry 220, a voltage generator 230, and a row decoder 240. Although not shown in FIG. 1, the peripheral circuit 200 may further include a data input/output circuit, an input/output interface, or the like. The peripheral circuit 200 may further include a column logic, a pre-decoder, a temperature sensor, a command decoder, an address decoder, or the like. In some embodiments, the memory device 10 herein may refer to a non-volatile memory device.

The memory cell array 100 may be connected to the page buffer circuit 210 through bit lines BL and connected to the row decoder 240 through word lines WL, string select lines SSL, and ground select lines GSL.

The memory cell array 100 may include a plurality of memory blocks BLK1 to BLKz. Each of the memory blocks BLK1 to BLKz may have a planar structure or a three-dimensional (3D) structure. The memory cell array 100 may include at least one selected from the group consisting of a single-level cell (SLC) block including SLCs, a multi-level cell (MLC) block including MLCs, a triple-level cell (TLC) block including TLCs, and a quad-level cell (QLC) block including QLCs. For example, some of the memory blocks BLK1 to BLKz may correspond to SLC blocks and the other memory blocks may correspond to MLC, TLC, or QLC blocks.

Each of the memory blocks BLK1 to BLKz may include a plurality of memory cells. For example, the memory cells may include flash memory cells. Hereinafter, embodiments will be described using the case that the memory cells are NAND flash memory cells as an example. However, embodiments are not limited thereto. In some embodiments, the memory cells may be resistive memory cells, such as resistive random access memory (ReRAM) cells, phase-change RAM (PRAM) cells, or magnetic RAM (MRAM) cells.

In some embodiments, the memory cell array 100 may include a 3D memory cell array, which may include a plurality of NAND strings. However, embodiments are not limited thereto. In some embodiments, the memory cell array 100 may include a two-dimensional (2D) memory cell array, which may include a plurality of NAND strings in row and column directions.

Based on a command CMD, an address ADDR, and a control signal CTRL, the control circuitry 220 may output various control signals, e.g., a voltage control signal CTRL_vol, a row address X-ADDR, and a column address Y-ADDR, for programming data to the memory cell array 100, reading data from the memory cell array 100, or erasing data from the memory cell array 100. The control circuitry 220 may hereby generally control various operations of the memory device 10.

The voltage generator 230 may generate various kinds of voltages for performing program, read, and erase operations of the memory cell array 100, based on the voltage control signal CTRL_vol. In detail, the voltage generator 230 may generate a word line voltage VWL, such as a program voltage, a read voltage, a pass voltage, an erase verify voltage, or a program verify voltage. The voltage generator 230 may further generate a string select line voltage and a ground select line voltage, based on the voltage control signal CTRL_vol.

In response to the row address X-ADDR, the row decoder 240 may select one of the memory blocks BLK1 to BLKz, one of the word lines WL of the selected memory block, and one of the string select lines SSL. The page buffer circuit 210 may select some of the bit lines BL in response to the column address Y-ADDR. In detail, the page buffer circuit 210 may operate as a write driver or a sense amplifier according to an operation mode.

The page buffer circuit 210 may include a plurality of page buffers PB respectively connected to the bit lines BL.

The memory cell array 100 and the peripheral circuit 200 may be respectively included in first and second semiconductor layers, which are stacked on each other. An external signal (e.g., CTRL, CMD, ADDR, or the like) from the outside of the memory device 10 may be received through an external signal pad formed outside the first semiconductor layer. The external signal may be provided to the peripheral circuit 200 through an external signal wire, which passes through or extends into the first semiconductor layer and at least a portion of the second semiconductor layer.

According to some embodiments, the size of the memory device 10 may be reduced by limiting the position of a region in which the external signal pad and the external signal wire are formed in each of the first and second semiconductor layers.

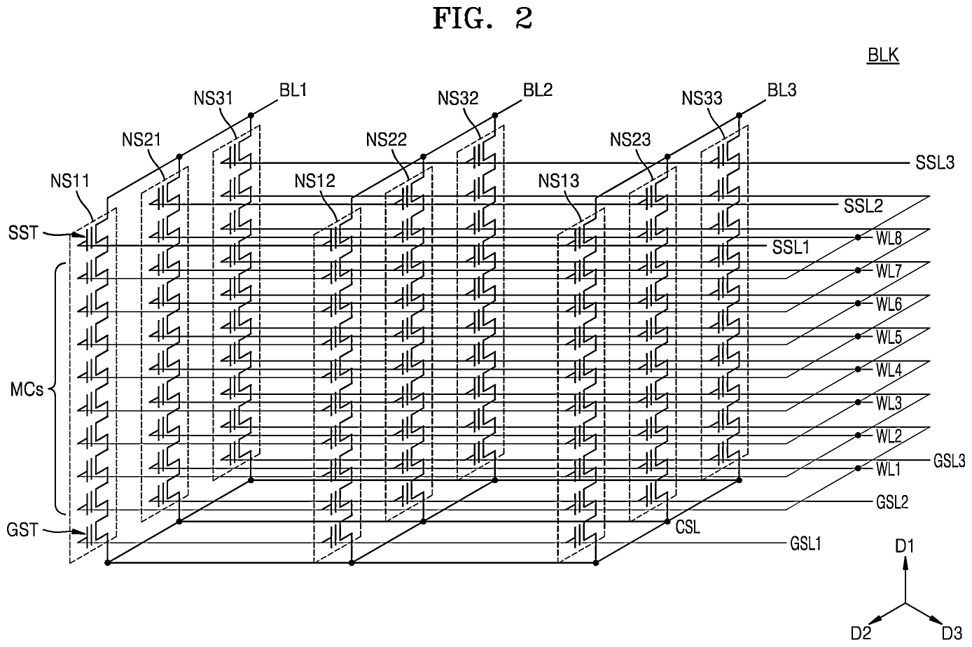

FIG. 2 is a circuit diagram of a memory block BLK according to some embodiments. A direction that is perpendicular to a substrate may be referred to as a first direction D1. A second direction D2 may be perpendicular to the first direction D1. A third direction D3 may be perpendicular to the first direction D1 and the second direction D2.

Referring to FIG. 2, the memory block BLK may correspond to one of the memory blocks BLK1 through BLKz in FIG. 1. The memory block BLK may include NAND strings NS11 through NS33, of which each (e.g., NS11) may include a string select transistor SST, a plurality of memory cells MCs, and a ground select transistor GST that are connected in series to one another. The transistors, e.g., the string select transistor SST and the ground select transistor GST, and the memory cells MCs included in each NAND string may form a stack structure on a substrate in a vertical direction.

Word lines WL1 to WL8 may extend in a second horizontal direction and first to third bit lines BL1 to BL3 may extend in a first horizontal direction. The NAND strings NS11, NS21, and NS31 may be between the first bit line BL1 and a common source line CSL. The NAND strings NS12, NS22, and NS32 may be between the second bit line BL2 and the common source line CSL. The NAND strings NS13, NS23, and NS33 may be between the third bit line BL3 and the common source line CSL. The string select transistor SST may be connected to a corresponding one among string select lines SSL1 to SSL3. Each of the memory cells MCs may be connected to a corresponding one among the word lines WL1 to WL8. The ground select transistor GST may be connected to a corresponding one among ground select lines GSL1 to GSL3. The string select transistor SST may be connected to a corresponding one among the first to third bit lines BL1 to BL3 and the ground select transistor GST may be connected to the common source line CSL. Here, the numbers of NAND strings, word lines, bit lines, ground select lines, and string select lines may vary with embodiments.

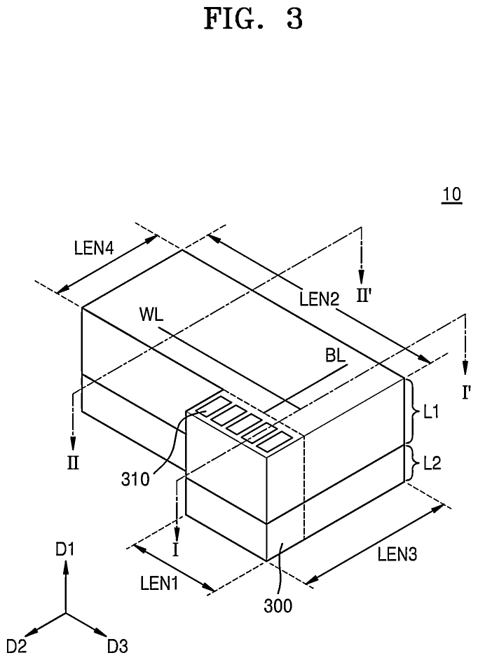

FIG. 3 illustrates an example structure of the memory device 10 of FIG. 1.

Here, a direction that is perpendicular to a substrate may be referred to as a first direction D1. A second direction D2 may be perpendicular to the first direction D1. A third direction D3 may be perpendicular to the first direction D1 and the second direction D2.

Referring to FIG. 3, the memory device 10 may include a first semiconductor layer L1 and a second semiconductor layer L2. The first semiconductor layer L1 may be stacked on the second semiconductor layer L2 in the vertical direction, i.e., the first direction D1. In detail, the second semiconductor layer L2 may be below the first semiconductor layer L1 in the first direction D1.

In an embodiment, the memory cell array 100 in FIG. 1 may be formed in the first semiconductor layer L1 and the peripheral circuit 200 in FIG. 1 may be formed in the second semiconductor layer L2. Accordingly, the memory device 10 may have a cell-over-periphery (COP) structure, in which the memory cell array 100 is above the peripheral circuit 200. According to the COP structure, an area in a horizontal direction (i.e., the second and third directions D2 and D3) may be effectively reduced, and the integration density of the memory device 10 may be increased.

In some embodiments, the second semiconductor layer L2 may include a substrate. The peripheral circuit 200 may be formed in the second semiconductor layer L2 by forming transistors and metal patterns, which interconnect the transistors, on the substrate. After the peripheral circuit 200 is formed in the second semiconductor layer L2, the first semiconductor layer L1 including the memory cell array 100 may be formed. Metal patterns, which electrically connect word lines WL and bit lines BL of the memory cell array 100 to the peripheral circuit 200 in the second semiconductor layer L2, may be formed. For example, the word lines WL may extend in the third direction D3 and the bit lines BL may extend in the second direction D2.

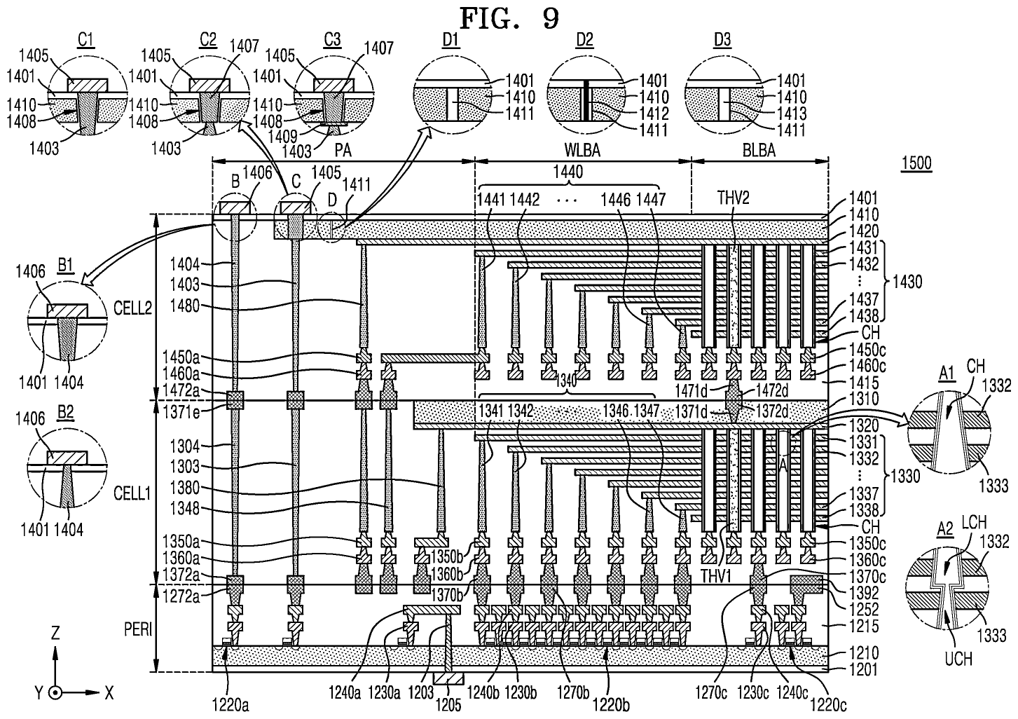

As described above, the memory device 10 may have a COP structure, but embodiments are not limited thereto. For example, the memory device 10 may have a chip-to-chip (C2C) structure. In this case, the first semiconductor layer L1 may correspond to an upper chip and the second semiconductor layer L2 may correspond to a lower chip. In the C2C structure, the first semiconductor layer L1 may include the memory cell array 100 in FIG. 1, which is formed on a first wafer, and the second semiconductor layer L2 may include the peripheral circuit 200 in FIG. 1, which is formed on a second wafer. The first semiconductor layer L1 and the second semiconductor layer L2 may be connected to each other in a bonding manner. For example, a bonding metal (e.g., an upper bonding metal patterns 1370c in FIG. 9) formed on an uppermost metal layer of the first semiconductor layer L1 may be electrically connected to a bonding metal formed on an uppermost metal layer of the second semiconductor layer L2. For example, when the bonding metal includes copper (Cu), the bonding manner may be Cu-Cu bonding. For example, the first semiconductor layer L1 and the second semiconductor layer L2 are stacked at a wafer level. For example, the first semiconductor layer L1 and the second semiconductor layer L2 are stacked at a chip level.

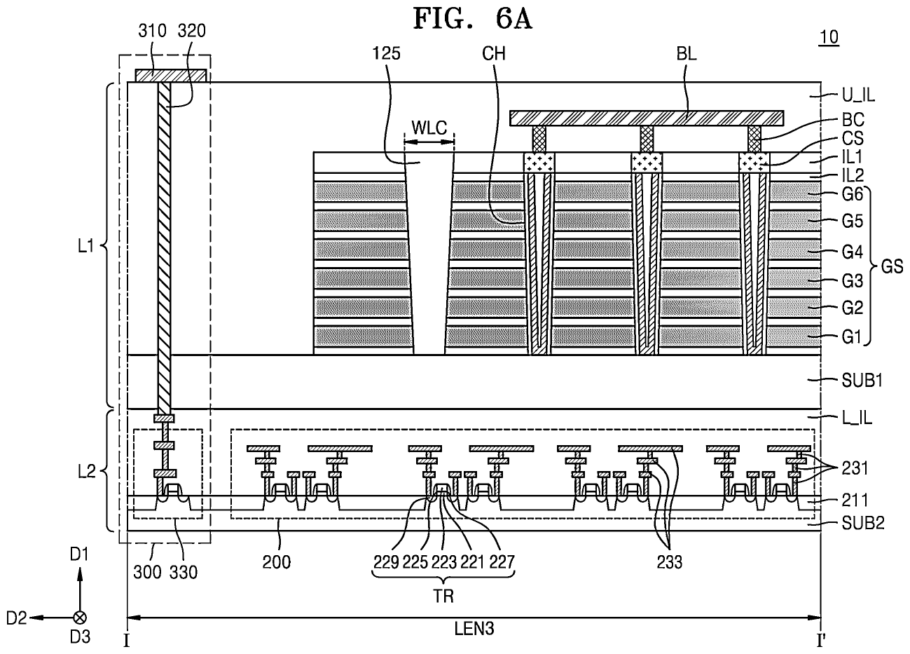

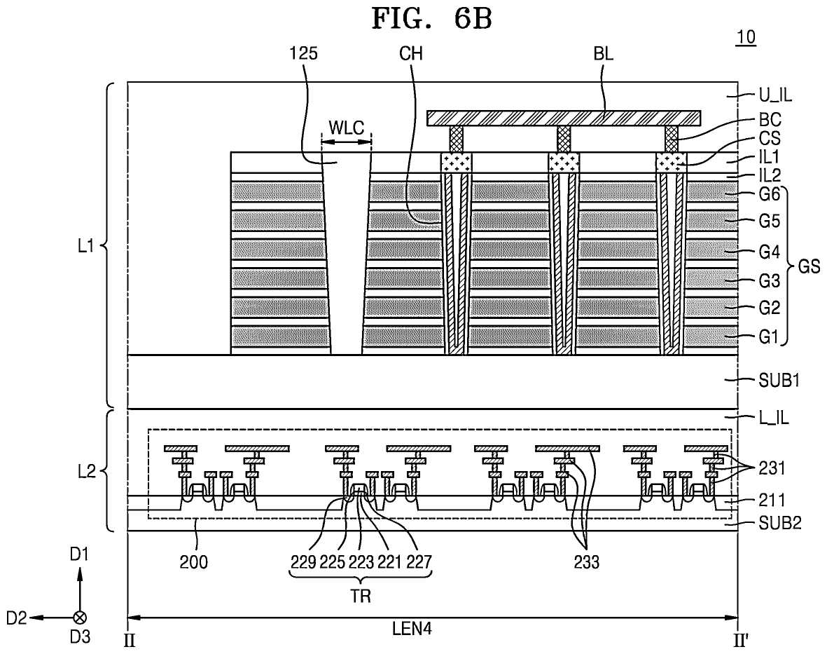

The memory device 10 may include a protrusion structure 300. The protrusion structure 300 may include a plurality of input/output pads 310. In some embodiments, the protrusion structure 300 may be referred to as an external connection unit, an external peripheral circuit unit, an outer periphery, or a pad area. The detailed configuration of the protrusion structure 300 is described below with reference to FIGS. 6A and 6B.

The input/output pads 310 may be formed on or in an upper portion of the first semiconductor layer L1 and may electrically connect the memory device 10 to an external device through a bonding wire. For example, the external device may refer to a host, a memory controller, or the like.

In some embodiments, the memory device 10 may include a first surface and a second surface, which are spaced apart from each other in the second direction D2 that is perpendicular to the first direction D1. The memory device 10 may include a third surface and a fourth surface, which extend from the first surface to the second surface, i.e., in the second direction D2. The protrusion structure 300 may protrude or extend from the first surface of the memory device 10. One side (perpendicular to the third direction D3) of the protrusion structure 300 may be coplanar with the third surface of the memory device 10.

In some embodiments, a first length LEN1 of the protrusion structure 300 in the third direction D3 may be less than half a second length LEN2 of the memory device 10 in the third direction D3.

In some embodiments, a third length LEN3 in the second direction D2 of the third surface of the memory device 10, which is coplanar with one surface of the protrusion structure 300, may be greater than a fourth length LEN4 in the second direction D2 of the fourth surface facing the third surface of the memory device 10.

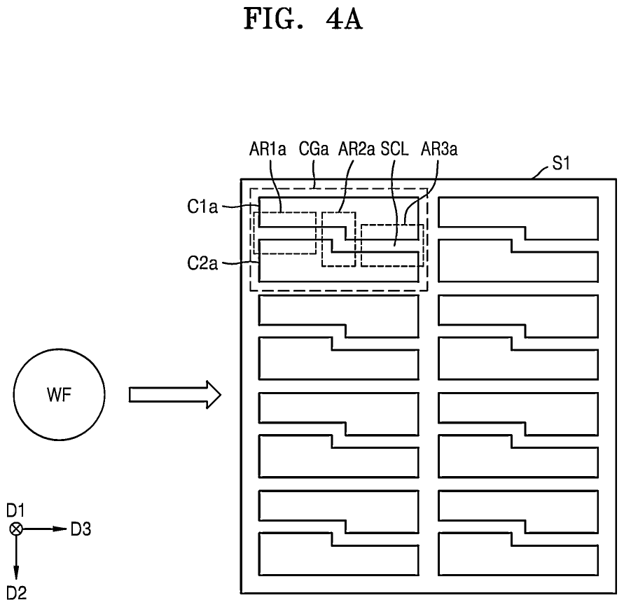

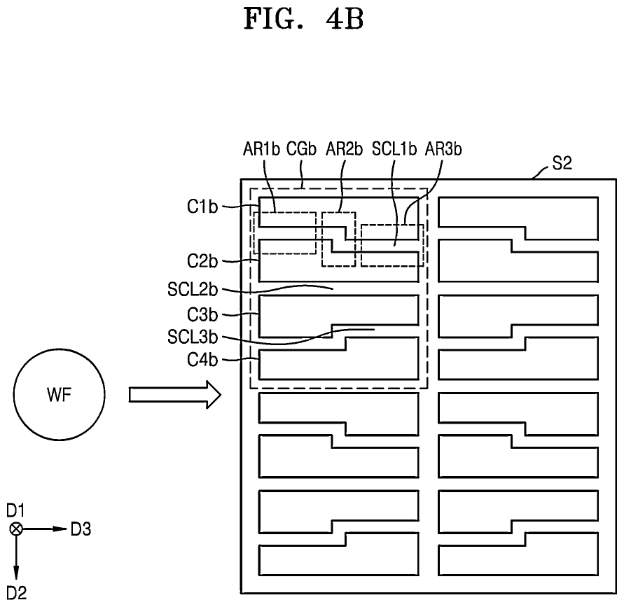

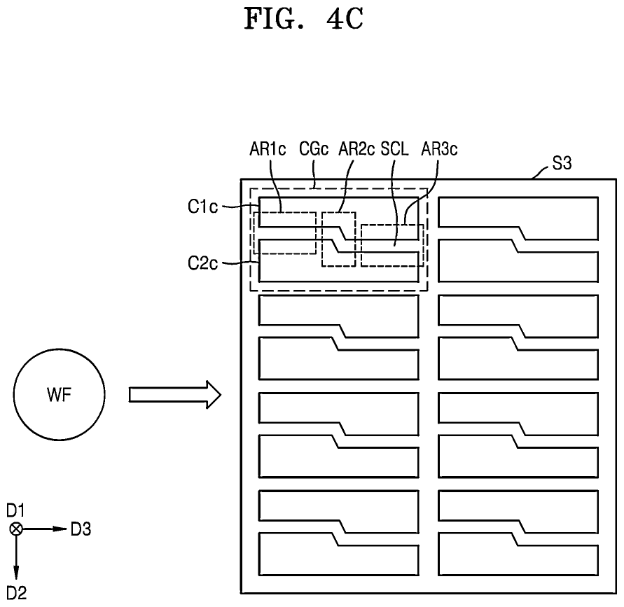

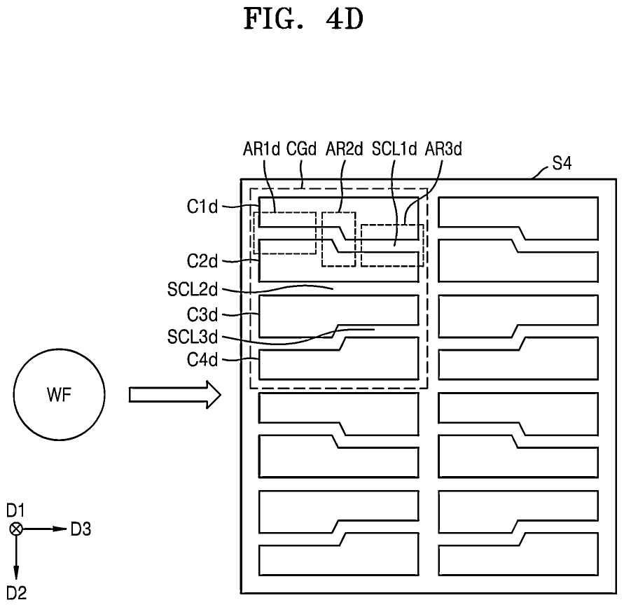

FIGS. 4A to 4D are diagrams illustrating the arrangement of a memory device on a wafer, according to some embodiments.

FIGS. 4A to 4D illustrate the formation of the memory device 10 on a wafer WF according to some embodiments. Herein, the memory device 10 may be referred to as a semiconductor chip or a chip. Photolithography may be performed on the wafer WF by using exposure equipment, and a plurality of shots may be formed on the wafer WF. Here, each shot may be formed according to the pattern of a reticle used in the exposure equipment.

FIG. 4A shows a first shot S1 among the shots formed on the wafer WF. The first shot S1 may include a plurality of chip groups CGa. Each of the chip groups CGa may include a first chip C1a and a second chip C2a. Each of the first chip C1a and the second chip C2a may correspond to the memory device 10 of FIG. 3. Although it is illustrated in FIG. 4A that there are eight chip groups in the first shot S1, it is just an example. The first shot S1 may include less or more chip groups.

In some embodiments, the first chip C1a and the second chip C2a may be spaced apart from each other in the second direction D2. The first chip C1a and the second chip C2a may be arranged to be symmetrical along a scribe lane SCL as an origin. At this time, the scribe lane SCL between the first chip C1a and the second chip C2a may be divided into a first area AR1a, a second area AR2a, and a third area AR3a. The first area AR1a and the third area AR3a may be spaced apart from each other in the second direction D2, and the second area AR2a between the first area AR1a and the third area AR3a may be vertical. In other words, the second area AR2a of the scribe lane SCL may extend in the second direction D2.

In some embodiments, a line for division may be located in the scribe lane SCL. A semiconductor facility may focus a laser beam on the line for division, and the wafer WF may be divided into a plurality of semiconductor chips along the line for division.

FIG. 4B shows a second shot S2 among the shots formed on the wafer WF. The second shot S2 may include a plurality of chip groups CGb. Each of the chip groups CGb may include first to fourth chips C1b to C4b. Each of the first to fourth chips C1b to C4b may correspond to the memory device 10 of FIG. 3. Although it is illustrated in FIG. 4B that there are four chip groups in the second shot S2, it is just an example. The second shot S2 may include less or more chip groups.

In some embodiments, the first to fourth chips C1b to C4b may be spaced apart from one another in the second direction D2. The first chip C1b and the second chip C2b may be arranged to be symmetrical along a scribe lane SCL1b as an origin. The third chip C3b and the fourth chip C4b may be arranged to be symmetrical along a scribe lane SCL3b as an origin. The first chip C1b and the fourth chip C4b may be arranged to be symmetrical along a second scribe lane SCL2b. The second chip C2b and the third chip C3b may be arranged to be symmetrical along a second scribe lane SCL2b. At this time, the first scribe lane SCL1b between the first chip C1b and the second chip C2b may be divided into a first area AR1b, a second area AR2b, and a third area AR3b. The first area AR1b and the third area AR3b may be spaced apart from each other in the second direction D2, and the second area AR2b between the first area AR1b and the third area AR3b may be vertical. In other words, the second area AR2b of the first scribe lane SCL1b may extend in the second direction D2. Similar to the first scribe lane SCL1b, the third scribe lane SCL3b between the third chip C3b and the fourth chip C4b may be divided into three areas, and redundant descriptions thereof are omitted.

In some embodiments, a line for division may be located in each of the first to third scribe lanes SCL1b, SCL2b, and SCL3b. A semiconductor facility may focus a laser beam on the line for division, and the wafer WF may be divided into a plurality of semiconductor chips along the line for division.

FIG. 4C shows a third shot S3 among the shots formed on the wafer WF. The third shot S3 may include a plurality of chip groups CGc. Each of the chip groups CGc may include a first chip C1c and a second chip C2c. In some embodiments, the third shot S3 in FIG. 4C may be configured similarly to the first shot S1 in FIG. 4A. A scribe lane SCL between the first chip C1c and the second chip C2c may be divided into a first area AR1c, a second area AR2c, and a third area AR3c. The first area AR1c and the third area AR3c may be spaced apart from each other in the second direction D2 and the second area AR2c between the first area AR1c and the third area AR3c may be oblique.

In some embodiments, a line for division may be located in the scribe lane SCL. A semiconductor facility may focus a laser beam on the line for division, and the wafer WF may be divided into a plurality of semiconductor chips along the line for division.

FIG. 4D shows a fourth shot S4 among the shots formed on the wafer WF. The fourth shot S4 may include a plurality of chip groups CGd. Each of the chip groups CGd may include first to fourth chips C1d to C4d. In some embodiments, the fourth shot S4 in FIG. 4D may be configured similarly to the second shot S2 in FIG. 4B. A first scribe lane SCL1d between the first chip C1d and the second chip C2d may be divided into a first area AR1d, a second area AR2d, and a third area AR3d. The first area AR1d and the third area AR3d may be spaced apart from each other in the second direction D2, and the second area AR2d between the first area AR1d and the third area AR3d may be oblique. Similar to the first scribe lane SCL1d, a third scribe lane SCL3d between the third chip C3d and the fourth chip C4d may be divided into three areas, and redundant descriptions thereof are omitted.

In some embodiments, a line for division may be located in each of the first to third scribe lanes SCL1d, SCL2d, and SCL3d. A semiconductor facility may focus a laser beam on the line for division, and the wafer WF may be divided into a plurality of semiconductor chips along the line for division.

As shown in FIGS. 4A to 4D, one side of each chip may protrude or extend and chips in a chip group may be arranged in origin or line symmetry with each other. In this case, the chips may be arranged closer to each other in the second direction D2 than chips having no protruding or extending sides (i.e., chips having a rectangular top surface). In other words, assuming that chip groups include the same number of chips, the length in the second direction D2 of each of the chip groups CGa and CGb may decrease compared to the case where chips have no protruding or extending sides. Accordingly, the length in the second direction D2 of each of the first shot S1 and the second shot S2 may decrease as compared to the case where chips have no protruding or extending sides. Consequently, when a pattern is formed on the wafer WF by using a reticle having a pattern corresponding to the first shot S1 or the second shot S2, according to some embodiments, more semiconductor chips may be formed and net die per wafer may increase.

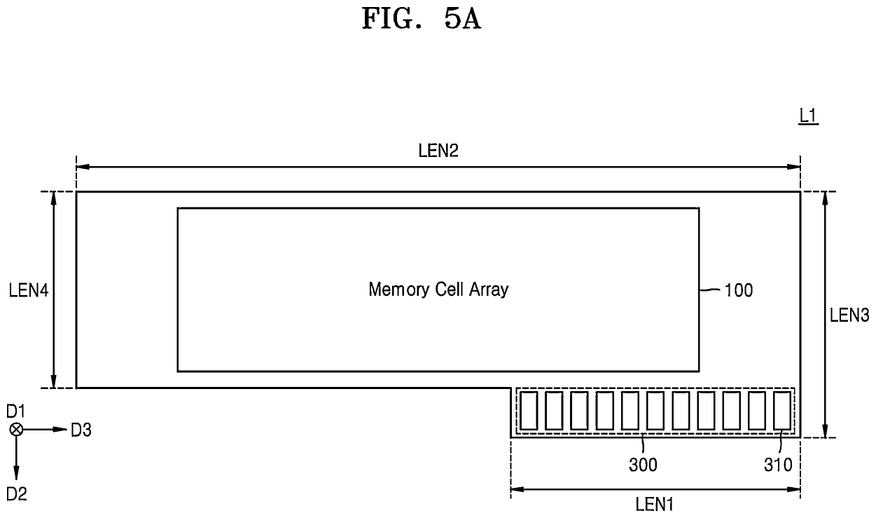

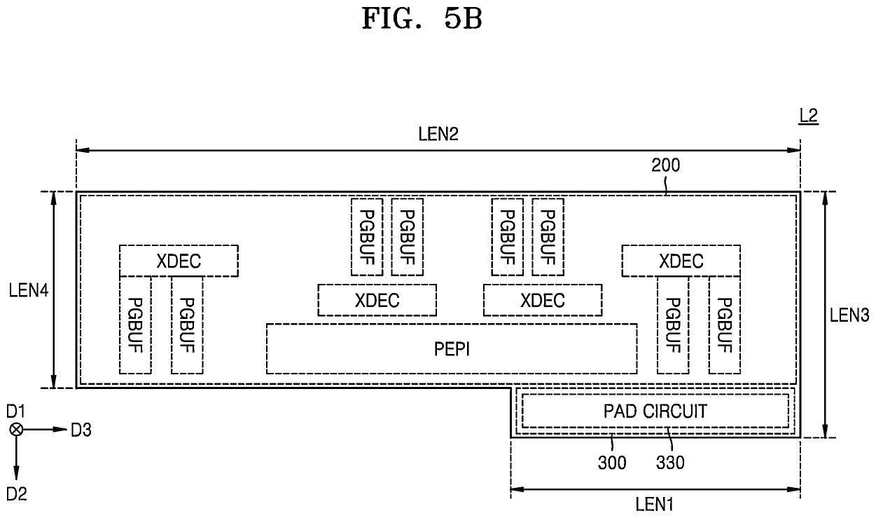

FIG. 5A is a layout diagram of the first semiconductor layer L1 of the memory device 10, according to some embodiments. FIG. 5B is a layout diagram of the second semiconductor layer L2 of the memory device 10, according to some embodiments.

Referring to FIG. 5A, the memory cell array 100 may be formed in the first semiconductor layer L1 of the memory device 10. The memory device 10 may include the protrusion structure 300. The protrusion structure 300 may be formed across the first semiconductor layer L1 and the second semiconductor layer L2. The protrusion structure 300 may include the input/output pads 310 formed in the first semiconductor layer L1.

Word lines in the memory cell array 100 may be activated independently of each other by a plurality of row decoders, and operations (e.g., a write operation and a read operation) of the memory cell array 100 may be controlled independently of each other by a plurality of page buffers. The memory cell array 100 may have a vertical stack structure. In detail, the memory cell array 100 may have the circuit configuration shown in FIGS. 2 and 3.

The memory device 10 may be electrically connected to an external device through the input/output pads 310. In some embodiments, the input/output pads 310 may be in an upper portion of at least a portion of the memory cell array 100. In other words, a portion of the memory cell array 100, which vertically overlaps the input/output pads 310, may correspond to an upper portion of an at least a portion of an outer area of the memory cell array 100, in which a channel hole (not shown) is not arranged.

A plurality of input/output pad contacts (not shown) may be respectively below the input/output pads 310. The input/output pad contacts may respectively and electrically connect the input/output pads 310 to a pad circuit 330 (in FIG. 5B). The input/output pad contacts are described with reference to FIGS. 6A and 6B below.

Referring to FIG. 5B, the peripheral circuit 200 and the pad circuit 330 may be formed in the second semiconductor layer L2. Peripheral circuits may be arranged according to the position of the memory cell array 100.

Page buffers PGBUF, row decoders XDEC, and other peripheral circuits PERI may overlap the memory cell array 100 in a direction (e.g., the first direction D1) that is perpendicular to the substrate. For example, the other peripheral circuits PERI may include a latch circuit, a cache circuit, or a sense amplifier. However, this is just one embodiment, and various modifications may be made therein.

The protrusion structure 300 may include the pad circuit 330 formed in the second semiconductor layer L2. In an embodiment, the pad circuit 330 may include an electrostatic discharge (ESD) circuit, a pull-up/pull-down driver, or a data input/output circuit.

FIGS. 6A and 6B are cross-sectional views of the memory device 10 according to some embodiments. In detail, FIG. 6A is a cross-sectional view of the memory device 10 taken along line I-I′ in FIG. 3. FIG. 6B is a cross-sectional view of the memory device 10 taken along line II-II′ in FIG. 3.

Referring to FIG. 6A, the memory device 10 may include the memory cell array 100, the peripheral circuit 200, and the protrusion structure 300. The memory cell array 100 may be formed on a first substrate SUB1. The protrusion structure 300 may be formed across the first semiconductor layer L1 and the second semiconductor layer L2. The protrusion structure 300 may include the input/output pads 310, a plurality of input/output pad contacts 320, and the pad circuit 330. The memory device 10 may be electrically connected to an external device through the input/output pads 310. The pad circuit 330 may be electrically connected to the input/output pads 310 through the input/output pad contacts 320, which pass through or extend into a portion of the first semiconductor layer L1.

The memory cell array 100 may include gate conductive layers GS that are spaced apart from each other. Although only first to sixth gate conductive layers GS1 to GS6 are illustrated in FIGS. 6A and 6B, there may be less or more gate conductive layers. Each of the gate conductive layers GS may be divided by a word line cut region 125 having a width WLC. Second insulating films IL2 may be among the gate conductive layers GS. A plurality of channel structures CS may be insulated from each other by a first insulating film IL1. Channel holes CH may each extend in the first direction, which is perpendicular to the top surface of the first substrate SUB1, through the gate conductive layers GS and the second insulating layers IL2. The bottom surface of each of the channel holes CH may be in contact with the top surface of the first substrate SUB1. The channel holes CH may be spaced apart from one another in the second direction D2 and the third direction D3. A plurality of bit line contacts BC may electrically connect the channel structures CS to a bit line BL. The channel structures CS and the bit line BL may be covered with or overlapped by an upper insulating layer U_IL.

In some embodiments, the channel holes CH may include polysilicon doped with an impurity or polysilicon that is not doped with an impurity. Each of the channel holes CH may have a cup shape (or a cylindrical shape with a closed bottom) that extends in the first direction D1.

The peripheral circuit 200 and the pad circuit 330 may be formed on a second substrate SUB2. Each of the peripheral circuit 200 and the pad circuit 330 may include at least one transistor TR. Transistors TR, lower contacts 231, and lower conductive lines 233 may form the peripheral circuit 200 and the pad circuit 330. For example, the transistors TR may form the row decoder 240, the page buffer circuit 210, and the control circuit 220 in FIG. 1. Each of the transistors TR may include a gate insulating film 221, a gate electrode 223, a capping pattern 225, a gate spacer 227, and source/drain regions 229. An isolation film 211 may be in the second substrate SUB2. The isolation film 211 may define an active region in the second substrate SUB2. For example, the isolation film 211 may include silicon oxide.

The gate insulating film 221 may be between the gate electrode 223 and the second substrate SUB2. The capping pattern 225 may be on the gate electrode 223. The gate spacer 227 may cover the respective sidewalls of the gate insulating film 221, the gate electrode 223, and the capping pattern 225. The source/drain regions 229 may be in the second substrate SUB2 and respectively adjacent to opposite sides of the gate electrode 223.

The lower conductive lines 233 may be electrically connected to the transistors TR through the lower contacts 231. For example, each of the transistors TR may correspond to an N-channel metal-oxide semiconductor (NMOS) transistor or a P-channel MOS (PMOS) transistor. Each of the transistors TR may be of a planar type or a gate-all-around type. The lower contacts 231 and the lower conductive lines 233 may include a conductive material such as metal. The peripheral circuit 200, the pad circuit 330, the lower contacts 231, and the lower conductive lines 233 may be covered with or overlapped by a lower insulating layer L_IL.

Referring to FIG. 6B, the memory device 10 of FIG. 6B may have a similar structure to the memory device 10 of FIG. 6A. However, because FIG. 6A is a cross-sectional view of the memory device 10 taken along line I-I′ and FIG. 6B is a cross-sectional view of the memory device 10 taken along line II-II′, the protrusion structure 300 may not be in the cross-sectional view of FIG. 6B. Accordingly, the third length LEN3 may be greater than the fourth length LEN4.

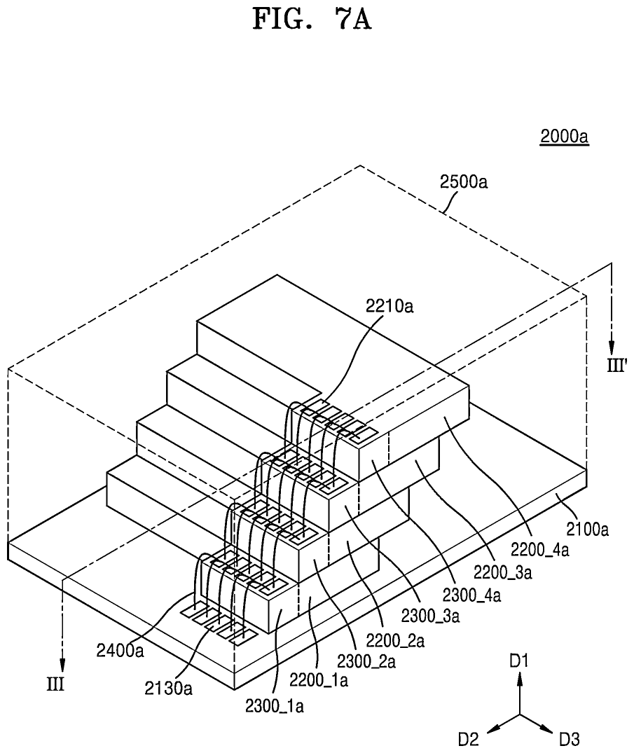

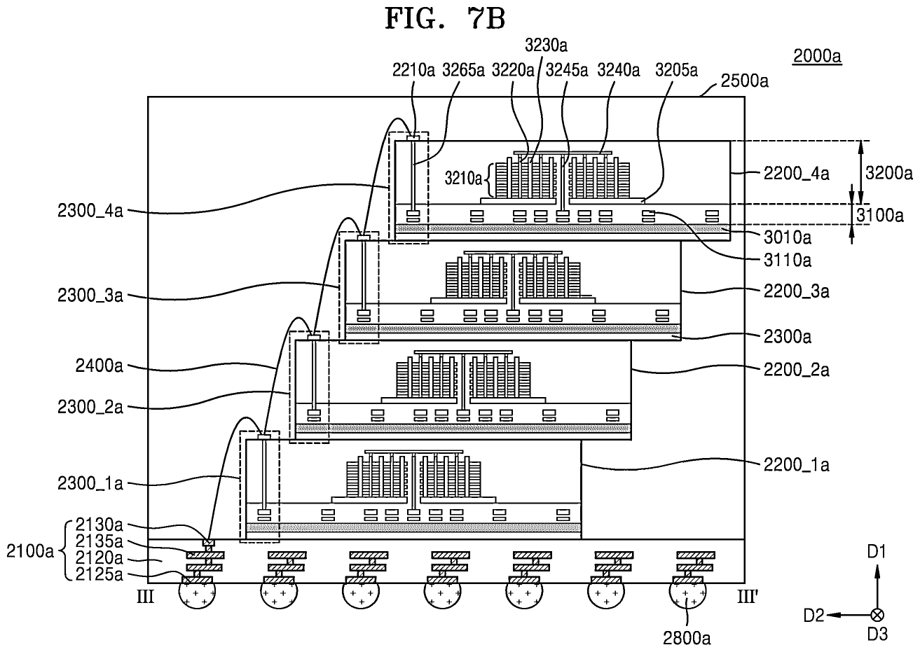

FIGS. 7A and 7B are diagrams illustrating a memory device according to an embodiment. In detail, FIG. 7A is a perspective view of a memory package 2000a. FIG. 7B is a cross-sectional view of the memory package 2000a taken along line III-III′ in FIG. 7A. FIGS. 7A and 7B may be described with reference to FIG. 3, and redundant descriptions thereof may be omitted.

The memory package 2000a of FIGS. 7A and 7B may include a plurality of memory devices 10 of FIG. 3, which are stacked in the first direction D1. The memory package 2000a of FIGS. 7A and 7B may be an embodiment of a semiconductor package. Each of first to fourth semiconductor chips 2200_1a to 2200_4a in FIGS. 7A and 7B may correspond to the memory device 10 of FIG. 3.

Referring to FIG. 7A, the memory package 2000a may include a package substrate 2100a. The package substrate 2100a may correspond to a printed circuit board (PCB). Referring to FIG. 7B, the package substrate 2100a may include a package substrate body 2120a, package upper pads 2130a, package lower pads 2125a, and internal wires 2135a. The package upper pads 2130a may be in the top surface of the package substrate body 2120a or exposed by the top surface of the package substrate body 2120a. The package lower pads 2125a may be in the bottom surface of the package substrate body 2120a or exposed by the bottom surface of the package substrate body 2120a. The internal wires 2135a may be in the package substrate body 2120a and may electrically connect the package upper pads 2130a to the package lower pads 2125a. The package upper pads 2130a may be electrically connected to connection structures 2400a. The package lower pads 2125a may be connected to an external device through conductive connectors 2800a. In other words, the package substrate 2100a may be configured to electrically connect an external device to the memory package 2000a. The memory package 2000a may include adhesive layers 2300a respectively on the bottom surfaces of the first to fourth semiconductor chips 2200_1a to 2200_4a. The memory package 2000a may include a molding layer 2500a on the package substrate 2100a to cover or overlap the first to fourth semiconductor chips 2200_1a to 2200_4a and the connection structures 2400a.

Each of the first to fourth semiconductor chips 2200_1a to 2200_4a may include a semiconductor substrate 3010a, a first structure 3100a, and a second structure 3200a, wherein the first structure 3100a and the second structure 3200a are sequentially stacked on the semiconductor substrate 3010a. The first structure 3100a may include a peripheral circuit region including peripheral wires 3110a. The second structure 3200a may include a source structure 3205a, a stacked structure 3210a on the source structure 3205a, vertical structures 3220a, isolation structures 3230a, and a bit line 3240a electrically connected to the vertical structures 3220a, wherein the vertical structures 3220a and the isolation structures 3230a pass through the stacked structure 3210a. Although only four semiconductor chips are illustrated in FIGS. 7A and 7B, it is just an example, and the memory package 2000a may include less or more semiconductor chips.

Each of the first to fourth semiconductor chips 2200_1a to 2200_4a may include a through wire 3245a, which is electrically connected to the peripheral wires 3110a of the first structure 3100a and extends into the second structure 3200a. The through wire 3245a may pass through or extend into the stacked structure 3210a. Although not shown, the through wire 3245a may be outside the stacked structure 3210a. Each of the first to fourth semiconductor chips 2200_1a to 2200_4a may further include an input/output pad electrically connected to the peripheral wires 3110a of the first structure 3100a.

Each of the first to fourth semiconductor chips 2200_1a to 2200_4a may include input/output pads 2210a. The input/output pads 2210a may respectively correspond to the input/output pads 310 in FIG. 3. Each of the first to fourth semiconductor chips 2200_1a to 2200_4a may include input/output contacts 3265a. The input/output contacts 3265a may respectively correspond to the input/output contacts 320 in FIG. 6A.

The first semiconductor chip 2200_1a may include a first protrusion structure 2300_1a. The first semiconductor chip 2200_1a may be stacked on the package substrate 2100a in the first direction D1. The first semiconductor chip 2200_1a may include a first surface and a second surface, which are spaced apart from each other in the second direction D2. The first semiconductor chip 2200_1a may include a third surface and a fourth surface, which extend from the first surface to the second surface. The first protrusion structure 2300_1a may protrude or extend outwards from the first surface of the first semiconductor chip 2200_1a. The first semiconductor chip 2200_1a may have a COP structure. In FIGS. 7A and 7B, a layer in an upper portion of the first semiconductor chip 2200_1a may be referred to as a first semiconductor layer and a layer in a lower portion of the first semiconductor chip 2200_1a may be referred to as a second semiconductor layer.

The second semiconductor chip 2200_2a may include a second protrusion structure 2300_2a. The second semiconductor chip 2200_2a may be stacked on the first semiconductor chip 2200_1a in the first direction D1. The second semiconductor chip 2200_2a may include a fifth surface and a sixth surface, which are spaced apart from each other in the second direction D2. The second semiconductor chip 2200_2a may include a seventh surface and an eighth surface, which extend from the fifth surface to the sixth surface. The second protrusion structure 2300_2a may protrude or extend outwards from the fifth surface of the second semiconductor chip 2200_2a. The second semiconductor chip 2200_2a may have a COP structure. In FIGS. 7A and 7B, a layer in an upper portion of the second semiconductor chip 2200_2a may be referred to as a third semiconductor layer and a layer in a lower portion of the second semiconductor chip 2200_2a may be referred to as a fourth semiconductor layer.

In some embodiments, one side surface of the first protrusion structure 2300_1a may be coplanar with the third surface. One side surface of the second protrusion structure 2300_2a may be coplanar with the seventh surface. The third surface may be coplanar with the seventh surface.

In some embodiments, the second semiconductor chip 2200_2a may be stacked on the first semiconductor chip 2200_1a such that the first surface of the first semiconductor chip 2200_1a is closer to the fifth surface of the second semiconductor chip 2200_2a than the second surface of the first semiconductor chip 2200_1a is. In addition, the second semiconductor chip 2200_2a may be stacked on the first semiconductor chip 2200_1a such that the third surface of the first semiconductor chip 2200_1a is closer to the seventh surface of the second semiconductor chip 2200_2a than the fourth surface of the first semiconductor chip 2200_1a is.

In some embodiments, the second semiconductor chip 2200_2a may be stacked on the first semiconductor chip 2200_1a in a step shape in the first direction D1. The bottom surface of the second protrusion structure 2300_2a may not overlap the top surface of the first protrusion structure 2300_1a.

In some embodiments, a length of the first protrusion structure 2300_1a in the third direction D3 may be less than half a length of the first semiconductor chip 2200_1a in the third direction D3. A length of the second protrusion structure 2300_2a in the third direction D3 may be less than half a length of the second semiconductor chip 2200_2a in the third direction D3.

In some embodiments, a length in the second direction D2 of the third surface, which is coplanar with one side surface of the first protrusion structure 2300_1a, may be greater than a length in the second direction D2 of the fourth surface facing the third surface. A length in the second direction D2 of the seventh surface, which is coplanar with one side surface of the second protrusion structure 2300_2a, may be greater than a length in the second direction D2 of the eighth surface facing the seventh surface.

The third semiconductor chip 2200_3a may include a third protrusion structure 2300_3a and the fourth semiconductor chip 2200_4a may include a fourth protrusion structure 2300_4a. The third semiconductor chip 2200_3a and the fourth semiconductor chip 2200_4a may be stacked in a similar manner to the first semiconductor chip 2200_1a and the second semiconductor chip 2200_2a, and thus, redundant descriptions thereof are omitted.

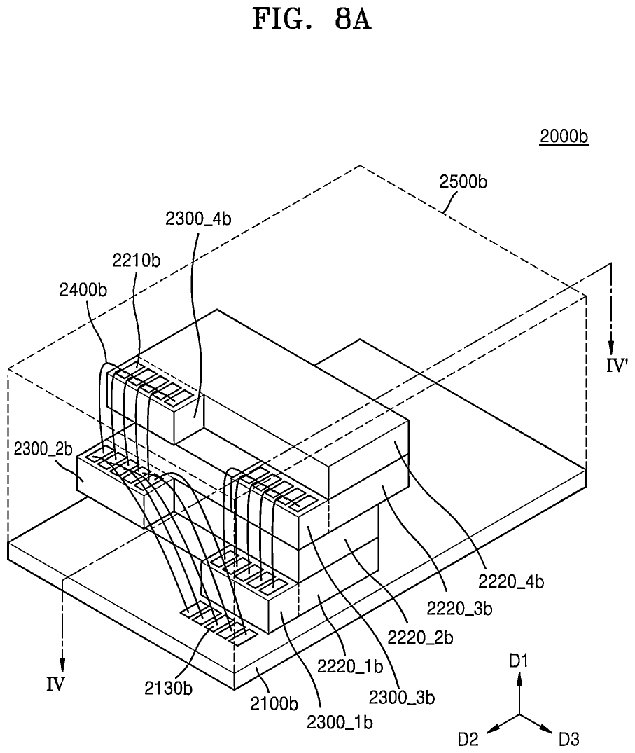

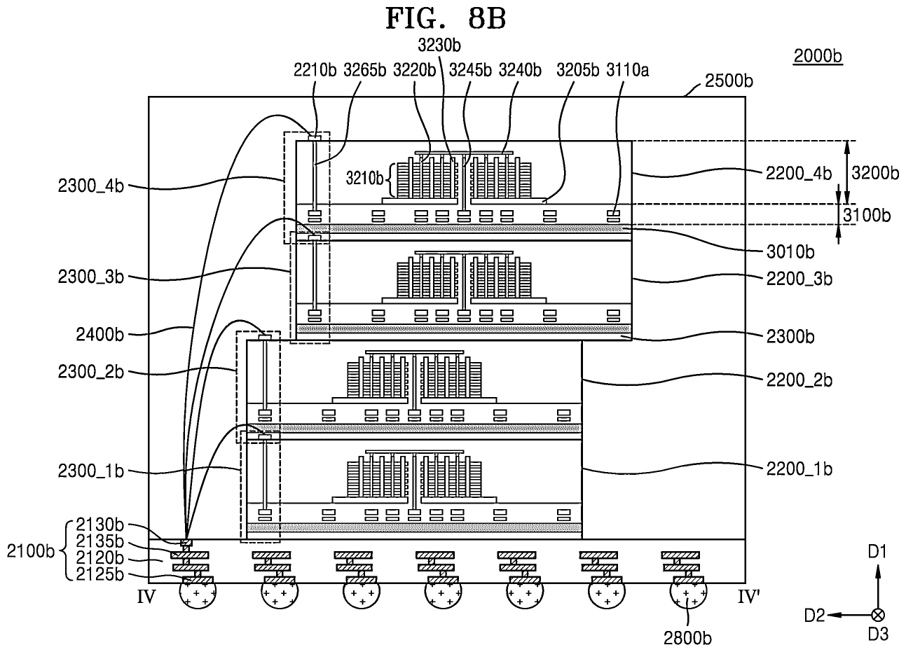

FIGS. 8A and 8B are diagrams illustrating a memory device according to some embodiments. In detail, FIG. 8A is a perspective view of a memory package 2000b. FIG. 8B is a cross-sectional view of the memory package 2000b taken along line IV-IV′ in FIG. 8A. FIGS. 8A and 8B may be described with reference to FIGS. 3, 7A, and 7B, and redundant descriptions thereof may be omitted.

The memory package 2000b of FIGS. 8A and 8B may have a similar configuration to the memory package 2000a of FIGS. 7A and 7B. However, first to fourth semiconductor chips 2200_1b to 2200_4b of the memory package 2000b of FIGS. 8A and 8B may be stacked on each other in a different structure than the first to fourth semiconductor chips 2200_1a to 2200_4a of the memory package 2000a of FIGS. 7A and 7B.

The first semiconductor chip 2200_1b may include a first protrusion structure 2300_1b. The first semiconductor chip 2200_1b may be stacked on the package substrate 2100b in the first direction D1. The first semiconductor chip 2200_1b may include a first surface and a second surface, which are spaced apart from each other in the second direction D2. The first semiconductor chip 2200_1b may include a third surface and a fourth surface, which extend from the first surface to the second surface. The first protrusion structure 2300_1b may protrude or extend outwards from the first surface of the first semiconductor chip 2200_1b. The first semiconductor chip 2200_1b may have a COP structure. In FIGS. 8A and 8B, a layer in an upper portion of the first semiconductor chip 2200_1b may be referred to as a first semiconductor layer and a layer in a lower portion of the first semiconductor chip 2200_1b may be referred to as a second semiconductor layer.

The second semiconductor chip 2200_2b may include a second protrusion structure 2300_2b. The second semiconductor chip 2200_2b may be stacked on the first semiconductor chip 2200_1b in the first direction D1. The second semiconductor chip 2200_2b may include a fifth surface and a sixth surface, which are spaced apart from each other in the second direction D2. The second semiconductor chip 2200_2b may include a seventh surface and an eighth surface, which extend from the fifth surface to the sixth surface. The second protrusion structure 2300_2b may protrude or extend outwards from the fifth surface of the second semiconductor chip 2200_2b. The second semiconductor chip 2200_2b may have a COP structure. In FIGS. 8A and 8B, a layer in an upper portion of the second semiconductor chip 2200_2b may be referred to as a third semiconductor layer and a layer in a lower portion of the second semiconductor chip 2200_2b may be referred to as a fourth semiconductor layer.

In some embodiments, one side surface of the first protrusion structure 2300_1b may be coplanar with the third surface. One side surface of the second protrusion structure 2300_2b may be coplanar with the eighth surface. The third surface may be spaced apart from the eighth surface in the third direction D3. In other words, the third surface may not be coplanar with the eighth surface.

In some embodiments, a length of the first protrusion structure 2300_1b in the third direction D3 may be less than half a length of the first semiconductor chip 2200_1b in the third direction D3. A length of the second protrusion structure 2300_2b in the third direction D3 may be less than half a length of the second semiconductor chip 2200_2b in the third direction D3.

In some embodiments, a length in the second direction D2 of the third surface, which is coplanar with one side surface of the first protrusion structure 2300_1b, may be greater than a length in the second direction D2 of the fourth surface facing the third surface. A length in the second direction D2 of the eighth surface, which is coplanar with one side surface of the second protrusion structure 2300_2b, may be greater than a length in the second direction D2 of the seventh surface facing the eighth surface.

The third semiconductor chip 2200_3b may include a third protrusion structure 2300_3b. The third semiconductor chip 2200_3b may be stacked on the second semiconductor chip 2200_2b in the first direction D1. The third semiconductor chip 2200_3b may include a ninth surface and a tenth surface, which are spaced apart from each other in the second direction D2. The third semiconductor chip 2200_3b may include an eleventh surface and a twelfth surface, which extend from the ninth surface to the tenth surface. The third protrusion structure 2300_3b may protrude or extend outwards from the ninth surface of the third semiconductor chip 2200_3b. The third semiconductor chip 2200_3b may have a COP structure. In FIGS. 8A and 8B, a layer in an upper portion of the third semiconductor chip 2200_3b may be referred to as a fifth semiconductor layer and a layer in a lower portion of the third semiconductor chip 2200_3b may be referred to as a sixth semiconductor layer. In some embodiments, the third protrusion structure 2300_3b may be spaced apart from the first protrusion structure 2300_1b in the second direction D2 and may be spaced apart from the second protrusion structure 2300_2b in the third direction D3.

The fourth semiconductor chip 2200_4b may include a fourth protrusion structure 2300_4b. The fourth semiconductor chip 2200_4b may be stacked on the third semiconductor chip 2200_3b in the same manner as the second semiconductor chip 2200_2b is stacked on the first semiconductor chip 2200_1b, and thus, redundant descriptions thereof are omitted.

When the first to fourth semiconductor chips 2200_1b to 2200_4b are stacked as shown in FIGS. 8A and 8B, the size of the memory package 2000b in the second direction D2 may be reduced. Accordingly, the memory package 2000b may be miniaturized.

FIG. 9 is a view illustrating a memory device 1500 according to some embodiments of the present disclosure.

Referring to FIG. 9, the memory device 1500 may have a C2C structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu-Cu bonding method. Alternatively, the bonding metal patterns may be formed of aluminum (Al) or tungsten (W).

The memory device 1500 may include the at least one upper chip including the cell region. For example, as illustrated in FIG. 9, the memory device 1500 may include two upper chips. However, the number of the upper chips is not limited thereto. In the case in which the memory device 1500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 1500. The first upper chip may be turned over or inverted and then may be connected to the lower chip by the bonding method, and the second upper chip may also be turned over or inverted and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 9. However, embodiments of the present disclosure is not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 1500 may include an external pad bonding region PA, a word line bonding region WLBA, and a bit line bonding region BLBA.

The peripheral circuit region PERI may include a first substrate 1210 and a plurality of circuit elements 1220a, 1220b and 1220c formed on the first substrate 1210. An interlayer insulating layer 1215 including one or more insulating layers may be provided on the plurality of circuit elements 1220a, 1220b and 1220c, and a plurality of metal lines electrically connected to the plurality of circuit elements 1220a, 1220b and 1220c may be provided in the interlayer insulating layer 1215. For example, the plurality of metal lines may include first metal lines 1230a, 1230b and 1230c connected to the plurality of circuit elements 1220a, 1220b and 1220c, and second metal lines 1240a, 1240b and 1240c formed on the first metal lines 1230a, 1230b and 1230c. The plurality of metal lines may be formed of at least one of various conductive materials. For example, the first metal lines 1230a, 1230b and 1230c may be formed of tungsten having a relatively high electrical resistivity, and the second metal lines 1240a, 1240b and 1240c may be formed of copper having a relatively low electrical resistivity.

The first metal lines 1230a, 1230b and 1230c and the second metal lines 1240a, 1240b and 1240c are illustrated and described in the present embodiments. However, embodiments of the present disclosure is not limited thereto. In certain embodiments, at least one or more additional metal lines may further be formed on the second metal lines 1240a, 1240b and 1240c. In this case, the second metal lines 1240a, 1240b and 1240c may be formed of aluminum, and at least some of the additional metal lines formed on the second metal lines 1240a, 1240b and 1240c may be formed of copper having an electrical resistivity lower than that of aluminum of the second metal lines 1240a, 1240b and 1240c.

The interlayer insulating layer 1215 may be disposed on the first substrate 1210 and may include an insulating material such as silicon oxide and/or silicon nitride.

Each of the first and second cell regions CELL1 and CELL2 may include at least one memory block. The first cell region CELL1 may include a second substrate 1310 and a common source line 1320. A plurality of word lines 1330 (1331, 1332, . . . 1337, and 1338) may be stacked on the second substrate 1310 in a direction (i.e., the Z-axis direction) perpendicular to a top surface of the second substrate 1310. String selection lines and a ground selection line may be disposed on and under the word lines 1330, and the plurality of word lines 1330 may be disposed between the string selection lines and the ground selection line. Likewise, the second cell region CELL2 may include a third substrate 1410 and a common source line 1420, and a plurality of word lines 1430 (1431, 1432, . . . 1437, and 1438) may be stacked on the third substrate 1410 in a direction (i.e., the Z-axis direction) perpendicular to a top surface of the third substrate 1410. Each of the second substrate 1310 and the third substrate 1410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region ‘A1’, the channel structure CH may be provided in the bit line bonding region BLBA and may extend in the direction perpendicular to the top surface of the second substrate 1310 to penetrate or extend into the word lines 1330, the string selection lines, and the ground selection line. The channel structure CH may include a data storage layer, a channel layer, and a filling insulation layer. The channel layer may be electrically connected to a first metal line 1350c and a second metal line 1360c in the bit line bonding region BLBA. For example, the second metal line 1360c may be a bit line and may be connected to the channel structure CH through the first metal line 1350c. The bit line 1360c may extend in a first direction (e.g., a Y-axis direction) parallel to the top surface of the second substrate 1310.

In some embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 1310 to penetrate or extend into the common source line 1320 and lower word lines 1331 and 1332. The lower channel LCH may include a data storage layer, a channel layer, and a filling insulation layer and may be connected to the upper channel UCH. The upper channel UCH may penetrate or extend into upper word lines 1333 to 1338. The upper channel UCH may include a data storage layer, a channel layer, and a filling insulation layer, and the channel layer of the upper channel UCH may be electrically connected to the first metal line 1350c and the second metal line 1360c. As a length of a channel increases, and due to characteristics of manufacturing processes, it may be difficult to form a channel having a substantially uniform width. The memory device 1500 according to the present embodiments may include a channel having improved width uniformity due to the lower channel LCH and the upper channel UCH, which are formed by the processes that are performed sequentially.

In the case in which the channel structure CH includes the lower channel LCH and the upper channel UCH as illustrated in the region ‘A2’, a word line located near a boundary between the lower channel LCH and the upper channel UCH may be a dummy word line. For example, the word lines 1332 and 1333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the lower word lines 1331 and 1332 penetrated or extended into by the lower channel LCH is less than the number of the upper word lines 1333 to 1338 penetrated or extended into by the upper channel UCH in the region ‘A2’. However, embodiments of the present disclosure is not limited thereto. In certain embodiments, the number of the lower word lines penetrated by the lower channel LCH may be equal to or more than the number of the upper word lines penetrated or extended into by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 9, the first through-electrode THV1 may penetrate or extend into the common source line 1320 and the plurality of word lines 1330. In certain embodiments, the first through-electrode THV1 may further penetrate or extend into the second substrate 1310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 1372d and a second through-metal pattern 1472d. The first through-metal pattern 1372d may be formed at a bottom end of the first upper chip including the first cell region CELL1, and the second through-metal pattern 1472d may be formed at a top end of the second upper chip including the second cell region CELL2. The first through-electrode THV1 may be electrically connected to the first metal line 1350c and the second metal line 1360c. A lower via 1371d may be formed between the first through-electrode THV1 and the first through-metal pattern 1372d, and an upper via 1471d may be formed between the second through-electrode THV2 and the second through-metal pattern 1472d. The first through-metal pattern 1372d and the second through-metal pattern 1472d may be connected to each other by the bonding method.

In addition, in the bit line bonding region BLBA, an upper metal pattern 1252 may be formed in an uppermost metal layer of the peripheral circuit region PERI, and an upper metal pattern 1392 having the same shape as the upper metal pattern 1252 may be formed in an uppermost metal layer of the first cell region CELL1. The upper metal pattern 1392 of the first cell region CELL1 and the upper metal pattern 1252 of the peripheral circuit region PERI may be electrically connected to each other by the bonding method. In the bit line bonding region BLBA, the bit line 1360c may be electrically connected to a page buffer included in the peripheral circuit region PERI. For example, some of the circuit elements 1220c of the peripheral circuit region PERI may constitute the page buffer, and the bit line 1360c may be electrically connected to the circuit elements 1220c constituting the page buffer through an upper bonding metal pattern 1370c of the first cell region CELL1 and an upper bonding metal pattern 1270c of the peripheral circuit region PERI.

Referring continuously to FIG. 9, in the word line bonding region WLBA, the word lines 1330 of the first cell region CELL1 may extend in a second direction (e.g., an X-axis direction) parallel to the top surface of the second substrate 1310 and may be connected to a plurality of cell contact plugs 1340 (1341, 1342, . . . 1346, and 1347). First metal lines 1350b and second metal lines 1360b may be sequentially connected onto the cell contact plugs 1340 connected to the word lines 1330. In the word line bonding region WLBA, the cell contact plugs 1340 may be connected to the peripheral circuit region PERI through upper bonding metal patterns 1370b of the first cell region CELL1 and upper bonding metal patterns 1270b of the peripheral circuit region PERI.

The cell contact plugs 1340 may be electrically connected to a row decoder included in the peripheral circuit region PERI. For example, some of the circuit elements 1220b of the peripheral circuit region PERI may constitute the row decoder, and the cell contact plugs 1340 may be electrically connected to the circuit elements 1220b constituting the row decoder through the upper bonding metal patterns 1370b of the first cell region CELL1 and the upper bonding metal patterns 1270b of the peripheral circuit region PERI. In some embodiments, an operating voltage of the circuit elements 1220b constituting the row decoder may be different from an operating voltage of the circuit elements 1220c constituting the page buffer. For example, the operating voltage of the circuit elements 1220c constituting the page buffer may be greater than the operating voltage of the circuit elements 1220b constituting the row decoder.

Likewise, in the word line bonding region WLBA, the word lines 1430 of the second cell region CELL2 may extend in the second direction (e.g., the X-axis direction) parallel to the top surface of the third substrate 1410 and may be connected to a plurality of cell contact plugs 1440 (1441, 1442, . . . 1446, and 1447). The cell contact plugs 1440 may be connected to the peripheral circuit region PERI through an upper metal pattern of the second cell region CELL2 and lower and upper metal patterns and a cell contact plug 1348 of the first cell region CELL1.

In the word line bonding region WLBA, the upper bonding metal patterns 1370b may be formed in the first cell region CELL1, and the upper bonding metal patterns 1270b may be formed in the peripheral circuit region PERI. The upper bonding metal patterns 1370b of the first cell region CELL1 and the upper bonding metal patterns 1270b of the peripheral circuit region PERI may be electrically connected to each other by the bonding method. The upper bonding metal patterns 1370b and the upper bonding metal patterns 1270b may be formed of aluminum, copper, or tungsten.

In the external pad bonding region PA, a lower metal pattern 1371e may be formed in a lower portion of the first cell region CELL1, and an upper metal pattern 1472a may be formed in an upper portion of the second cell region CELL2. The lower metal pattern 1371e of the first cell region CELL1 and the upper metal pattern 1472a of the second cell region CELL2 may be connected to each other by the bonding method in the external pad bonding region PA. Likewise, an upper metal pattern 1372a may be formed in an upper portion of the first cell region CELL1, and an upper metal pattern 1272a may be formed in an upper portion of the peripheral circuit region PERI. The upper metal pattern 1372a of the first cell region CELL1 and the upper metal pattern 1272a of the peripheral circuit region PERI may be connected to each other by the bonding method.

Common source line contact plugs 1380 and 1480 may be disposed in the external pad bonding region PA. The common source line contact plugs 1380 and 1480 may be formed of a conductive material such as a metal, a metal compound, and/or doped polysilicon. The common source line contact plug 1380 of the first cell region CELLI may be electrically connected to the common source line 1320, and the common source line contact plug 1480 of the second cell region CELL2 may be electrically connected to the common source line 1420. A first metal line 1350a and a second metal line 1360a may be sequentially stacked on the common source line contact plug 1380 of the first cell region CELL1, and a first metal line 1450a and a second metal line 1460a may be sequentially stacked on the common source line contact plug 1480 of the second cell region CELL2.

Input/output pads 1205, 1405 and 1406 may be disposed in the external pad bonding region PA. Referring to FIG. 9, a lower insulating layer 1201 may cover or overlap a bottom surface of the first substrate 1210, and a first input/output pad 1205 may be formed on the lower insulating layer 1201. The first input/output pad 1205 may be connected to at least one of a plurality of the circuit elements 1220a disposed in the peripheral circuit region PERI through a first input/output contact plug 1203 and may be separated from the first substrate 1210 by the lower insulating layer 1201. In addition, a side insulating layer may be disposed between the first input/output contact plug 1203 and the first substrate 1210 to electrically isolate the first input/output contact plug 1203 from the first substrate 1210.

An upper insulating layer 1401 covering or overlapping a top surface of the third substrate 1410 may be formed on the third substrate 1410. A second input/output pad 1405 and/or a third input/output pad 1406 may be disposed on the upper insulating layer 1401. The second input/output pad 1405 may be connected to at least one of the plurality of circuit elements 1220a disposed in the peripheral circuit region PERI through second input/output contact plugs 1403 and 1303, and the third input/output pad 1406 may be connected to at least one of the plurality of circuit elements 1220a disposed in the peripheral circuit region PERI through third input/output contact plugs 1404 and 1304.

In some embodiments, the third substrate 1410 may not be disposed in a region in which the input/output contact plug is disposed. For example, as illustrated in a region ‘B’, the third input/output contact plug 1404 may be separated from the third substrate 1410 in a direction parallel to the top surface of the third substrate 1410 and may penetrate or extend into an interlayer insulating layer 1415 of the second cell region CELL2 so as to be connected to the third input/output pad 1406. In this case, the third input/output contact plug 1404 may be formed by at least one of various processes.

In some embodiments, as illustrated in a region ‘B1’, the third input/output contact plug 1404 may extend in a third direction (e.g., the Z-axis direction), and a diameter of the third input/output contact plug 1404 may progressively increase toward the upper insulating layer 1401. In other words, a diameter of the channel structure CH described in the region ‘A1’ may progressively decrease toward the upper insulating layer 1401, but the diameter of the third input/output contact plug 1404 may progressively increase toward the upper insulating layer 1401. For example, the third input/output contact plug 1404 may be formed after the second cell region CELL2 and the first cell region CELL1 are bonded to each other by the bonding method.

In certain embodiments, as illustrated in a region ‘B2’, the third input/output contact plug 1404 may extend in the third direction (e.g., the Z-axis direction), and a diameter of the third input/output contact plug 1404 may progressively decrease toward the upper insulating layer 1401. In other words, like the channel structure CH, the diameter of the third input/output contact plug 1404 may progressively decrease toward the upper insulating layer 1401. For example, the third input/output contact plug 1404 may be formed together with the cell contact plugs 1440 before the second cell region CELL2 and the first cell region CELL1 are bonded to each other.

In certain embodiments, the input/output contact plug may overlap with the third substrate 1410. For example, as illustrated in a region ‘C’, the second input/output contact plug 1403 may penetrate the interlayer insulating layer 1415 of the second cell region CELL2 in the third direction (e.g., the Z-axis direction) and may be electrically connected to the second input/output pad 1405 through the third substrate 1410. In this case, a connection structure of the second input/output contact plug 1403 and the second input/output pad 1405 may be realized by various methods.

In some embodiments, as illustrated in a region ‘C1’, an opening 1408 may be formed to penetrate the third substrate 1410, and the second input/output contact plug 1403 may be connected directly to the second input/output pad 1405 through the opening 1408 formed in the third substrate 1410. In this case, as illustrated in the region ‘C1’, a diameter of the second input/output contact plug 1403 may progressively increase toward the second input/output pad 1405. However, embodiments of the present disclosure is not limited thereto, and in certain embodiments, the diameter of the second input/output contact plug 1403 may progressively decrease toward the second input/output pad 1405.

In certain embodiments, as illustrated in a region ‘C2’, the opening 1408 penetrating or extending into the third substrate 1410 may be formed, and a contact 1407 may be formed in the opening 1408. An end of the contact 1407 may be connected to the second input/output pad 1405, and another end of the contact 1407 may be connected to the second input/output contact plug 1403. Thus, the second input/output contact plug 1403 may be electrically connected to the second input/output pad 1405 through the contact 1407 in the opening 1408. In this case, as illustrated in the region ‘C2’, a diameter of the contact 1407 may progressively increase toward the second input/output pad 1405, and a diameter of the second input/output contact plug 1403 may progressively decrease toward the second input/output pad 1405. For example, the second input/output contact plug 1403 may be formed together with the cell contact plugs 1440 before the second cell region CELL2 and the first cell region CELL1 are bonded to each other, and the contact 1407 may be formed after the second cell region CELL2 and the first cell region CELL1 are bonded to each other.

In certain embodiments illustrated in a region ‘C3’, a stopper 1409 may further be formed on a bottom end of the opening 1408 of the third substrate 1410, as compared with the embodiments of the region ‘C2’. The stopper 1409 may be a metal line formed in the same layer as the common source line 1420. Alternatively, the stopper 1409 may be a metal line formed in the same layer as at least one of the word lines 1430. The second input/output contact plug 1403 may be electrically connected to the second input/output pad 1405 through the contact 1407 and the stopper 1409.

Like the second and third input/output contact plugs 1403 and 1404 of the second cell region CELL2, a diameter of each of the second and third input/output contact plugs 1303 and 1304 of the first cell region CELL1 may progressively decrease toward the lower metal pattern 1371e or may progressively increase toward the lower metal pattern 1371e.

Meanwhile, in some embodiments, a slit 1411 may be formed in the third substrate 1410. For example, the slit 1411 may be formed at a certain position of the external pad bonding region PA. For example, as illustrated in a region ‘D’, the slit 1411 may be located between the second input/output pad 1405 and the cell contact plugs 1440 when viewed in a plan view. Alternatively, the second input/output pad 1405 may be located between the slit 1411 and the cell contact plugs 1440 when viewed in a plan view.

In some embodiments, as illustrated in a region ‘D1’, the slit 1411 may be formed to penetrate or extend into the third substrate 1410. For example, the slit 1411 may be used to prevent or inhibit the third substrate 1410 from being finely cracked when the opening 1408 is formed. However, embodiments of the present disclosure is not limited thereto, and in certain embodiments, the slit 1411 may be formed to have a depth ranging from about 60% to about 70% of a thickness of the third substrate 1410.

In certain embodiments, as illustrated in a region ‘D2’, a conductive material 1412 may be formed in the slit 1411. For example, the conductive material 1412 may be used to discharge a leakage current occurring in driving of the circuit elements in the external pad bonding region PA to the outside. In this case, the conductive material 1412 may be connected to an external ground line.

In certain embodiments, as illustrated in a region ‘D3’, an insulating material 1413 may be formed in the slit 1411. For example, the insulating material 1413 may be used to electrically isolate the second input/output pad 1405 and the second input/output contact plug 1403 disposed in the external pad bonding region PA from the word line bonding region WLBA. Since the insulating material 1413 is formed in the slit 1411, it is possible to prevent or inhibit a voltage provided through the second input/output pad 1405 from affecting a metal layer disposed on the third substrate 1410 in the word line bonding region WLBA.

Meanwhile, in certain embodiments, the first to third input/output pads 1205, 1405 and 1406 may be selectively formed. For example, the memory device 1500 may be realized to include only the first input/output pad 1205 disposed on the first substrate 1210, to include only the second input/output pad 1405 disposed on the third substrate 1410, or to include only the third input/output pad 1406 disposed on the upper insulating layer 1401.

In some embodiments, at least one of the second substrate 1310 of the first cell region CELL1 or the third substrate 1410 of the second cell region CELL2 may be used as a sacrificial substrate and may be completely or partially removed before or after a bonding process. An additional layer may be stacked after the removal of the substrate. For example, the second substrate 1310 of the first cell region CELL1 may be removed before or after the bonding process of the peripheral circuit region PERI and the first cell region CELL1, and then, an insulating layer covering or overlapping a top surface of the common source line 1320 or a conductive layer for connection may be formed. Likewise, the third substrate 1410 of the second cell region CELL2 may be removed before or after the bonding process of the first cell region CELL1 and the second cell region CELL2, and then, the upper insulating layer 1401 covering or overlapping a top surface of the common source line 1420 or a conductive layer for connection may be formed.

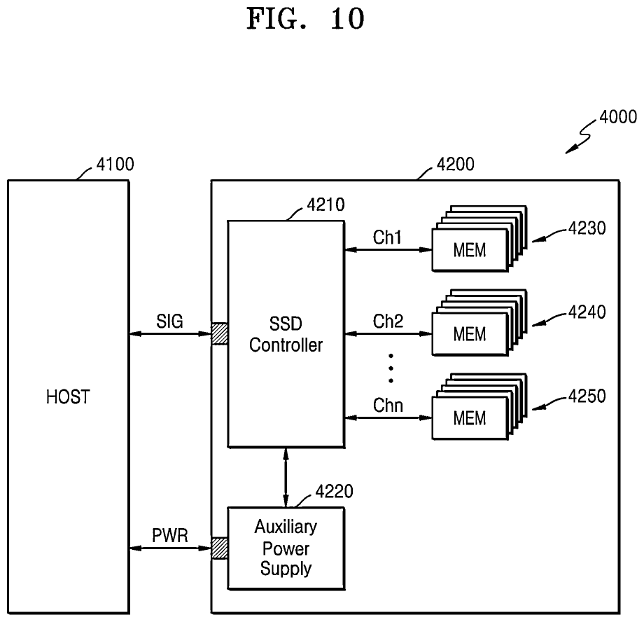

FIG. 10 is a block diagram of an example of applying a memory device according to embodiments to a solid-state drive (SSD) system 4000.

Referring to FIG. 10, an SSD system 4000 may include a host 4100 and an SSD 4200. The SSD 4200 may exchange signals SIG with the host 4100 through a signal connector and may receive power PWR through a power connector. The SSD 4200 may include an SSD controller 4210, an auxiliary power supply 4220, and memory devices 4230, 4240, and 4250. Each of the memory devices 4230, 4240, and 4250 may correspond to a vertical stack NAND flash memory device. In some embodiments, each of the memory devices 4230, 4240, and 4250 may be implemented by using the embodiments described above with reference to FIGS. 1 to 9.

While the present disclosure has been particularly shown and described with reference to embodiments thereof, it will be understood that various changes in form and details may be made therein without departing from the spirit and scope of the following claims.

What is claimed is:

1. A non-volatile memory device comprising:
a substrate;
a first semiconductor layer comprising a memory cell array on the substrate, wherein the memory cell array comprises a plurality of gate conductive layers and defines a plurality of channel holes, wherein the plurality of gate conductive layers are spaced apart in a first direction that is perpendicular to a top surface of the substrate, and wherein each of the plurality of channel holes extend into the plurality of gate conductive layers;
a second semiconductor layer comprising a peripheral circuit that is configured to write data to or read the data from the memory cell array, wherein the second semiconductor layer is on the first semiconductor layer; and
a protrusion structure comprising a wire that extends into at least a portion of the first semiconductor layer and at least a portion of the second semiconductor layer, wherein the protrusion structure extends from a first surface of the first semiconductor layer and from a first surface of the second semiconductor layer, and wherein the protrusion structure extends in a second direction that is perpendicular to the first direction.

2. The non-volatile memory device of claim 1, wherein:
a second surface of the first semiconductor layer is spaced apart from the first surface of the first semiconductor layer in the first direction;
a second surface of the second semiconductor layer is spaced apart from the first surface of the second semiconductor layer in the first direction;
a side surface of the protrusion structure is perpendicular to the first surface of the first semiconductor layer and the first surface of the second semiconductor layer;
the side surface of the protrusion structure is coplanar with a third surface of the first semiconductor layer and a third surface of the second semiconductor layer;
the third surface of the first semiconductor layer is perpendicular to the second surface of the first semiconductor layer; and
the third surface of the second semiconductor layer is perpendicular to the second surface of the second semiconductor layer.

3. The non-volatile memory device of claim 2, wherein the protrusion structure comprises:
a plurality of input/output pads that are on the first semiconductor layer and are configured to electrically connect the non-volatile memory device to an external device;
a pad circuit that is in the second semiconductor layer and electrically connected to the peripheral circuit; and
a plurality of input/output pad contacts that extend into the first semiconductor layer and are configured to electrically connect the plurality of input/output pads to the pad circuit.

4. The non-volatile memory device of claim 3, wherein the peripheral circuit and the pad circuit at least partially overlap each other in the second direction.

5. The non-volatile memory device of claim 2, wherein the memory cell array further comprises:
a plurality of cell strings comprising a plurality of memory cells, a plurality of word lines that are electrically connected to the plurality of memory cells, and a plurality of bit lines that are electrically connected to a first end of respective ones of the plurality of cell strings,
wherein the plurality of word lines extend in a third direction that is perpendicular to the first direction and the second direction, and
wherein the plurality of bit lines extend in the second direction.

6. The non-volatile memory device of claim 2, wherein:
a fourth surface of the first semiconductor layer opposes the third surface of the first semiconductor layer;
a fourth surface of the second semiconductor layer opposes the third surface of the second semiconductor layer;
a length of the third surface of the first semiconductor layer in the second direction is greater than a length of the fourth surface of the first semiconductor layer in the second direction; and a length of the third surface of the second semiconductor layer in the second direction is greater than a length of the fourth surface of the second semiconductor layer in the second direction.

7. The non-volatile memory device of claim 1, wherein a length of the protrusion structure in a third direction that is perpendicular to the first direction and the second direction is less than half of a length of the first semiconductor layer in the third direction or less than half of a length of the second semiconductor layer in the third direction.

8. A memory package comprising:
a package substrate configured to electrically connect an external device to the memory package;
a first memory device that extends in a first direction that is perpendicular to a top surface of the package substrate, wherein the first memory device comprises a first surface, a second surface, a third surface, and a fourth surface, wherein the first surface is spaced apart from the second surface in a second direction that is perpendicular to the first direction, and wherein the third surface and the fourth surface extend from the first surface to the second surface; and
a second memory device comprising a fifth surface, a sixth surface, a seventh surface, and an eighth surface, wherein the fifth surface is spaced apart from the sixth surface in the second direction, and wherein the seventh surface and the eighth surface extends from the fifth surface to the sixth surface,
wherein the first memory device comprises a first protrusion structure that extends from the first surface,
wherein the second memory device comprises a second protrusion structure that extends from the fifth surface,
wherein the second memory device is on the first memory device, and
wherein a bottom surface of the second protrusion structure overlaps at least a portion of the first memory device in the first direction.

9. The memory package of claim 8, wherein:
the first memory device comprises a first peripheral circuit;
the second memory device comprises a second peripheral circuit;
the first protrusion structure comprises:
a first semiconductor layer;
a second semiconductor layer;
a plurality of first input/output pads that are on the first semiconductor layer and are configured to electrically connect the first memory device to the external device;
a first pad circuit that is in the second semiconductor layer and is electrically connected to the first peripheral circuit; and
a plurality of first input/output pad contacts that extend into the first semiconductor layer and are configured to electrically connect the plurality of first input/output pads to the first pad circuit, and
the second protrusion structure comprises:
a third semiconductor layer;
a fourth semiconductor layer;
a plurality of second input/output pads that are on the third semiconductor layer and are configured to electrically connect the second memory device to the external device;
a second pad circuit that is in the fourth semiconductor layer and electrically connected to the second peripheral circuit; and
a plurality of second input/output pad contacts that extend into the third semiconductor layer and are configured to electrically connect the plurality of second input/output pads to the second pad circuit.

10. The memory package of claim 8, wherein a side surface of the first protrusion structure is coplanar with the third surface, a side surface of the second protrusion structure is coplanar with the seventh surface, and the third surface is coplanar with the seventh surface.

11. The memory package of claim 8, wherein:
the first surface of the first memory device is closer to the fifth surface of the second memory device than the second surface of the first memory device, and
the third surface of the first memory device is closer to the seventh surface of the second memory device than the fourth surface of the first memory device.

12. The memory package of claim 10, wherein:
a length of the first protrusion structure in a third direction that is perpendicular to the first direction and the second direction is less than half of a length of the first memory device in the third direction, and
a length of the second protrusion structure in the third direction is less than half of a length of the second memory device in the third direction.

13. The memory package of claim 10, wherein:
a length of the third surface in the second direction is greater than a length of the fourth surface in the second direction, and
a length of the seventh surface in the second direction is greater than a length of the eighth surface in the second direction.

14. The memory package of claim 8, wherein:
the second memory device partially overlaps the first memory device in the first direction, and
the bottom surface of the second protrusion structure does not overlap a top surface of the first protrusion structure in the first direction.

15. A memory package comprising:
a package substrate configured to electrically connect an external device to the memory package;
a first memory device that extends in a first direction that is perpendicular to a top surface of the package substrate, wherein the first memory device comprises a first surface, a second surface, a third surface, and a fourth surface, wherein the first surface is spaced apart from the second surface in a second direction that is perpendicular to the first direction, and wherein the third surface and the fourth surface extend from the first surface to the second surface; and
a second memory device comprising a fifth surface, a sixth surface, a seventh surface, and an eighth surface, wherein the fifth surface is spaced apart from the sixth surface in the second direction, and wherein the seventh surface and the eighth surface extend from the fifth surface to the sixth surface,
wherein the first memory device comprises a first protrusion structure that extends from the first surface,
wherein the second memory device comprises a second protrusion structure that extends from the fifth surface,
wherein the second memory device at least partially overlaps the first memory device in the first direction, and
wherein the first protrusion structure is spaced apart from the second protrusion structure in a third direction that is perpendicular to the first direction and the second direction.

16. The memory package of claim 15, wherein:
the first memory device comprises a first peripheral circuit;
the second memory device comprises a second peripheral circuit;
the first protrusion structure comprises:
a first semiconductor layer;
a second semiconductor layer;
a plurality of first input/output pads that are on the first semiconductor layer and are configured to electrically connect the first memory device to the external device;
a first pad circuit that is in the second semiconductor layer and electrically connected to the first peripheral circuit; and
a plurality of first input/output pad contacts that extend into the first semiconductor layer and are configured to electrically connect the plurality of first input/output pads to the first pad circuit, and
the second protrusion structure comprises:
a third semiconductor layer;
a fourth semiconductor layer;
a plurality of second input/output pads that are on the third semiconductor layer and are configured to electrically connect the second memory device to the external device;
a second pad circuit that is in the fourth semiconductor layer and electrically connected to the second peripheral circuit; and
a plurality of second input/output pad contacts that extend into the third semiconductor layer and are configured to electrically connect the plurality of second input/output pads to the second pad circuit.

17. The memory package of claim 15, wherein a side surface of the first protrusion structure is coplanar with the third surface, a side surface of the second protrusion structure is coplanar with the eighth surface, and the third surface is spaced apart from the eighth surface in the third direction.

18. The memory package of claim 15, wherein:
a length of the first protrusion structure in the third direction is less than half of a length of the first memory device in the third direction, and
a length of the second protrusion structure in the third direction is less than half of a length of the second memory device in the third direction.

19. The memory package of claim 15, wherein
a length of the third surface in the second direction is greater than a length of the fourth surface in the second direction, and
a length of the eighth surface in the second direction is greater than a length of the seventh surface in the second direction.

20. The memory package of claim 15, further comprising:
a third memory device comprising a ninth surface, a tenth surface, an eleventh surface, and a twelfth surface, wherein the ninth surface is spaced apart from the tenth surface in the second direction, and wherein the eleventh surface and the twelfth surface extend from the ninth surface to the tenth surface,
wherein the third memory device further comprising a third protrusion structure that extends from the ninth surface,
wherein the third protrusion structure overlaps the first protrusion structure in the second direction and is spaced apart from the second protrusion structure in the third direction, and
wherein the third memory device at least partially overlaps the second memory device in the first direction.
